(19) United States
(12) Patent Application Publication
(10) Pub. No.: US 2012/0255704 A1
(43) Pub. Date: Oct. 11, 2012

(54) IMAGE DISPLAY APPARATUS

(75) Inventor: Masaya Nakamichi, Moriguchi-shi (JP)

(73) Assignee: SANYO ELECTRIC CO., LTD., Osaka (JP)

(21) Appl. No.: 13/516,616

(22) PCT Filed: Dec. 8, 2010
(86) PCT No.: PCT/JP2010/072005

§ 371 Date: Jun. 15, 2012

(30) Foreign Application Priority Data
Dec. 18, 2009 (JP) 2009-287844
Dec. 18, 2009 (JP) 2009-287845

(51) Int. Cl. H05K 7/20; G01K 1/08

(52) U.S. Cl. 165/11.1; 361/695

(57) ABSTRACT

An image display apparatus according to the present invention includes an image display panel and a casing housing the image display panel therein. The casing has an image display window, through which a screen of the image display panel can he visually recognized from the outside. Here, the casing has a pair of ventilating ports passing from the outside thereof to the inside, and a channel passing between the screen of the image display panel and the image display window of the casing so as to allow the pair of ventilating ports to communicate with each other. Moreover, the casing has a fan for generating an air flow inside of the channel.

### TECHNICAL FIELD

The present invention relates to an image display apparatus provided with an image display panel.

### BACKGROUND ART

An image display apparatus of this type is provided with a casing housing an image display panel therein. The casing has an image display window, through which a screen of the image display panel can be visually recognized from the outside (see, for example, JP 2005-286987 A).

The image display apparatuses in the prior art have been designed on the assumption that most of them are installed indoors, and therefore, it is not conceived that the screen of the image display panel, could he heated by sunlight going through the image display window.

In recent years, there has been conceived that an image display apparatus provided with an image display panel is permanently installed outdoors or the image display apparatus is mounted in another apparatus such as a vending machine installed outdoors. An image display apparatus can be installed in a narrow site owing to its small thickness, and further, the apparatus can be hardly increased in size even when it is mounted in another apparatus such as a vending machine.

However, in the case where the image display apparatus in the prior art is permanently installed outdoors as it is or the image display apparatus in the prior art is mounted in another apparatus such as a vending machine as it is, sunlight is incident on the image display window, thereby raising a fear of occurrence of a malfunction of the image display panel due to an excessive increase in temperature of the screen of the image display panel.

### SUMMARY OF THE INVENTION

### Means for Solving the Problems

An image display apparatus according to a first aspect of the present invention includes an image display panel and a casing housing the image display panel therein, the casing having an image display window, through which a screen of the image display panel can be visually recognized from the outside.

Here, the casing has a pair of ventilating ports passing from the outside thereof to the inside, a channel passing between the screen of the image display panel and the image display window of the casing so as to allow the pair of ventilating ports to communicate with each other, and blowing means for generating an air flow inside of the channel.

An image display apparatus according to a second aspect of the present invention includes an image display panel and a casing housing the image display panel therein, the casing having an image display window, through which a screen of the image display panel can be visually recognized from the outside.

Here, the casing has a ventilator that allows the inside and outside of the casing to communicate with each other; and blowing means is provided for introducing air from the ventilator to the casing, the ventilator incorporating therein a pair of filters, one of which is disposed apart from the other filter at an area outside of an installation area of the other filter.

### BRIEF DESCRIPTION OF THE DRAWINGS

FIG. 1 is a front perspective view of an image display apparatus according to an embodiment of the present invention.

FIG. 2 is a rear perspective view of the image display apparatus.

FIG. 3 is a rear perspective view of the image display apparatus from which a back wall of a casing is removed.

FIG. 4 is a horizontal cross-sectional view of the image display apparatus.

FIG. 5 is a rear perspective view of the image display apparatus, a part of which is taken away.

FIG. 6 is a perspective view of a channel defining member provided in the image display apparatus.

FIG. 7 is an enlarged view of a section A shown in FIG. 4.

FIG. 8 is an enlarged view of a section B shown in FIG. 4.

FIG. 9 is a block diagram illustrating a configuration for notifying clogging in a filter inside of the image display apparatus.

FIG. 10 is an implementation example of the image display apparatus.

### DETAILED DESCRIPTION OF EMBODIMENTS

An embodiment according to the present invention will be specifically described with reference to the drawings.

1. Configuration of Image Display Apparatus

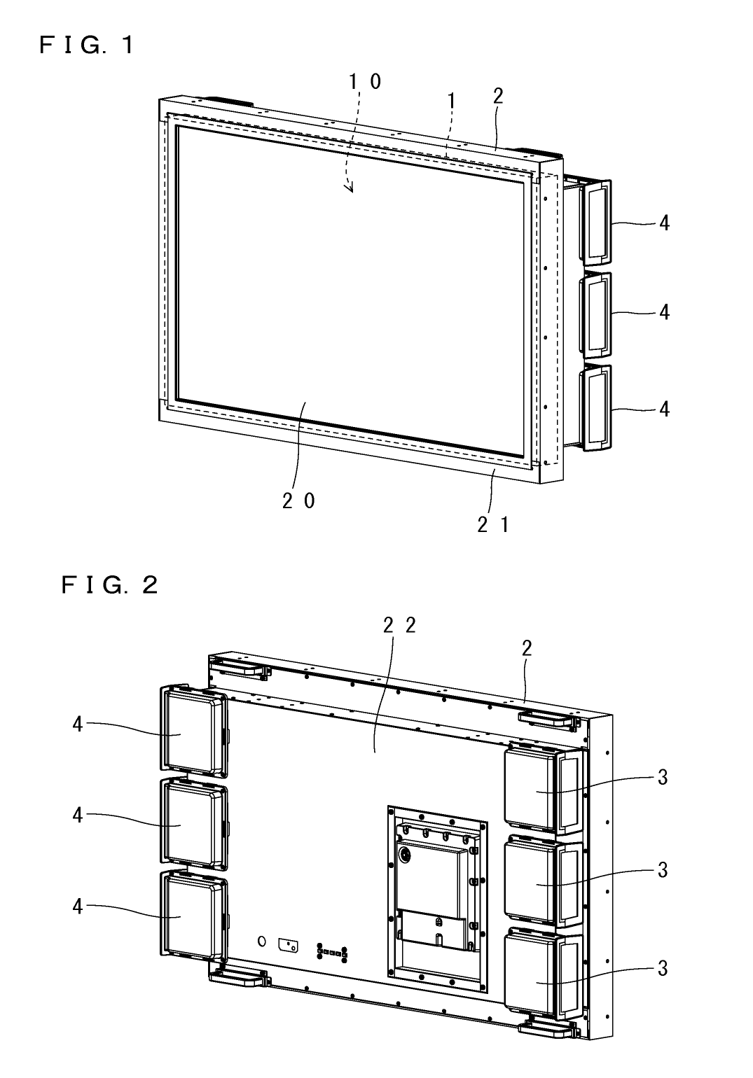

As shown in FIG. 1, an image display apparatus according to an embodiment of the present invention is provided with a liquid crystal display panel 1 and a casing 2 housing the liquid crystal display panel 1 therein. On a front wall 21 of the casing 2, an image display window 20 through which a screen 10 on the liquid crystal display panel 1 can be visually recognized from the outside is disposed. Here, the image display window 20 is made of a light translucent plate such as a glass plate. Moreover, the liquid crystal display panel 1 is disposed inside of the casing 2 with a clearance defined, between the screen 10 and the image display window 20.

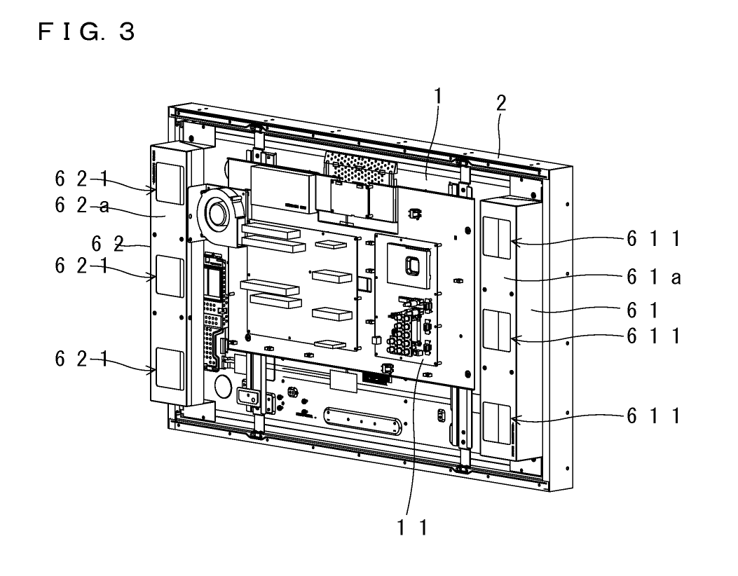

As shown in FIG. 3, a circuit board 11 for controlling the liquid crystal display panel 1 is housed in the casing 2 and is mounted on the back surface of the liquid crystal display panel 1.

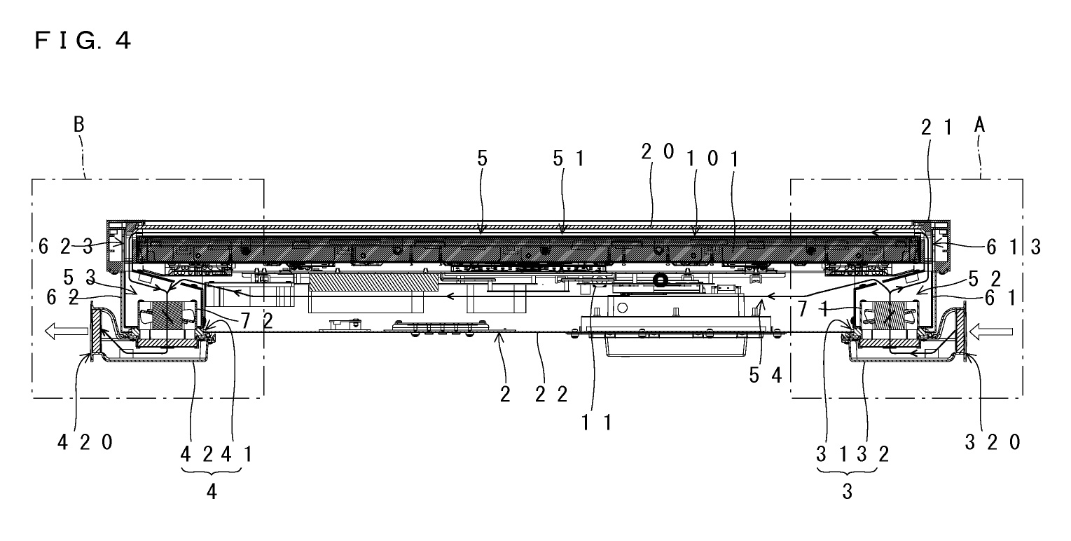

As shown in FIG. 4, on a back wall 22 of the casing 2, a lateral pair of ventilating ports 31 and 41 passing inward from the outside of the casing 2 are formed, and further, a pair of ducts 32 and 42 surrounding the pair of ventilating ports 31 and 41, respectively, are formed. The pair of ducts 32 and 42 extend sideways in directions opposite to each other along the back wall 22 of the casing 2 from the pair of ventilating ports 31 and 41 with opening ends 320 and 420 being oriented sideways. Hence, the pair of ventilating ports 31 and 41 and the pair of ducts 32 and 42 constitute a pair of ventilators 3 and 4 for allowing the inside and outside of the casing 2 to communicate with each other.

As shown in FIG. 2, the pair of ventilators 3 and 4 are disposed at she three positions, chat is, upper, middle, and lower stages on the back wall of the casing 2 in the present embodiment.

As shown in FIG. 4, a channel 5 is defined inside of the casing 2 in such a manner as to pass between the screen 10 of the liquid crystal display panel 1 and the image display window 20 of the casing 2 so as to allow the pair of ventilating ports 31 and 41 to communicate with each other. Specifically, the channel 5 includes a first channel portion 51 extending along the screen 10 of the liquid crystal display panel 1 and a pair of second channel portions 52 and 53 extending rearward from the first channel portion 51 through both of right and left sides of the liquid crystal display panel 1. The pair of second channel portions 52 and 53 communicate with the pair of ventilating ports 31 and 41, respectively.

Here, the first channel portion 51 is defined by the screen 10 of the liquid crystal display panel 1 and the image display window 20 of the casing 2. Additionally, the pair of second channel portions 52 and 53 are defined by a pair of channel defining members 61 and 62, respectively, as shown in FIG. 3.

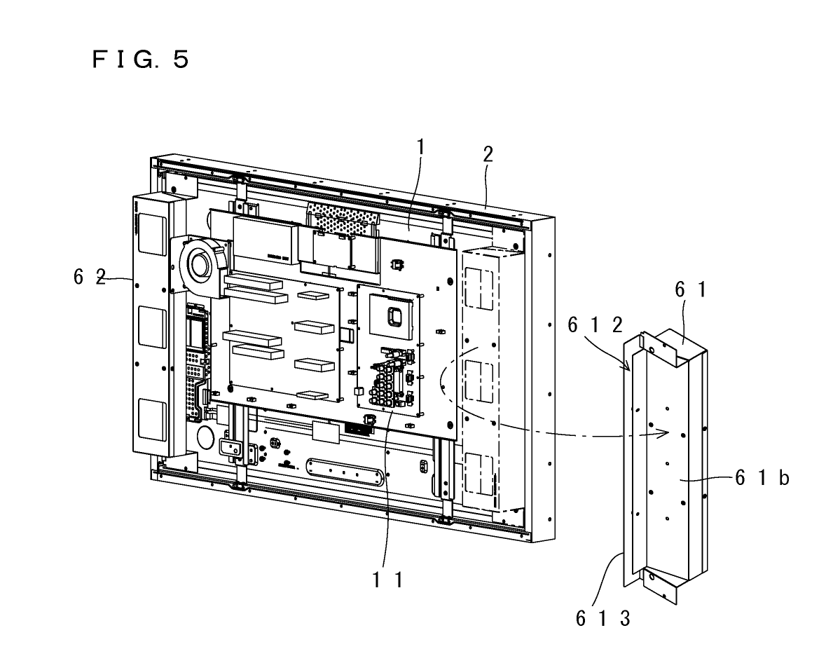

As shown in FIG. 3, openings 611 are formed at the three positions, that is, upper, middle, and lower stages of a back wall 61a of the channel defining member 61 positioned on the right as viewed from the back surface side (hereinafter, simply referred to as “right”) out of the pair of channel defining members 61 and 62. In the meantime, as shown in FIG. 5, a passage defining portion 613 defining a slit-like passage 612 extending vertically is provided in a forward projecting manner on a front wall 61b of the channel defining member 61. Furthermore, the three openings 611, 611, and 611 communicate with the passage 612 via a space defined in the right channel defining matter 61.

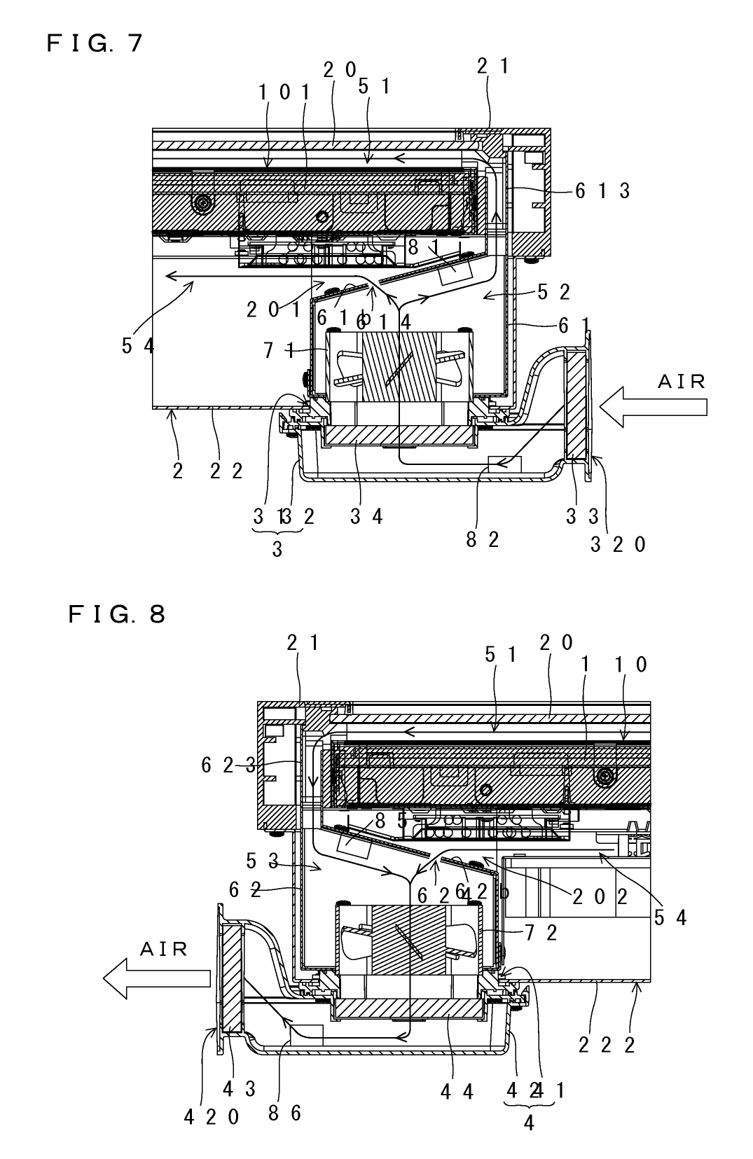

As shown in FIGS. 4 and 7, when the image display apparatus has been assembled, the passage defining portion 613 of the right channel defining member 61 is defined between the right side surface of the liquid crystal display panel 1 and the casing 2, and therefore, the space defined inside of the right channel defining member 61, that is, the second channel portion 52 communicates with the first channel portion 51. Moreover, when the image display apparatus has been assembled, she three openings 611, 611, and 611 formed in the right channel defining member 61 face the three ventilating ports 31, 31, and. 31 formed at the three positions, that is, the upper, middle, and lower stages on the back wall 22 of the casing 2, respectively. In this manner, the space defined inside of the right channel defining member 61 communicates with a space defined in the ventilator 3 via each of the openings 611 and each of the ventilating ports 31.

Here, as shown in FIG. 7, the front wall 61b of the right channel defining member 61 is inclined with respect to the back surface of the liquid crystal display panel 1. As a consequence, the second channel portion 52 defined by the right channel defining member 61 is gradually expanded rearward after passing the right side surface of the liquid crystal display panel 1. Moreover, a clearance 201 passing a space near the center of the back surface of the liquid crystal display panel 1 is formed between the front wall 61b of the right channel defining member 61 and the back surface of the liquid crystal display panel 1.

As shown in FIG. 3, openings 621 are formed at the three positions, that is, upper, middle, and lower stages of a back wall 62a of the channel defining member 62 positioned on the left as viewed from the back surface side (hereinafter, simply referred to as “left”) out of the pair of channel defining members 61 and 62. In the meantime, a passage defining portion. 623 defining a slit-like passage extending vertically projects forward on a front wall 62b of the channel defining member 62 (see FIG. 4), like the right channel defining member 61 (see FIG. 5).

As shown in FIG. 4, when the image display apparatus has been assembled, the passage defining portion 623 of the left channel defining member 62 is defined between the left side surface of the liquid crystal display panel 1 and the casing 2, and therefore, the space defined inside of the left channel defining member 62, that is, the second channel portion 53 communicates with the first channel portion 51. Moreover, when the image display apparatus has been assembled, the three openings 621, 621, and 621 formed in the left channel defining member 62 face the three ventilating ports 41, 41, and 41 formed at the three positions, that is, the upper, middle, and lower stages on the back wall 22 of the casing 2, respectively. In this manner, the space defined inside of the left channel defining member 62 communicates with a space defined in the ventilator 4 via each of the openings 621 and each of the ventilating ports 41.

Here, as shown in FIG. 8, the front wail 62b of the left channel defining member 62 is inclined with respect to the back surface of the liquid crystal display panel 1. As a consequence, the second channel portion 53 defined by the left channel defining member 62 is gradually expanded rearward after passing the left side surface of the liquid crystal display panel 1. Moreover, a clearance 202 passing a space near the center of the back surface of the liquid crystal display panel 1 is formed between the front wall 62b of the left channel defining member 62 and the back surface of the liquid crystal display panel 1.

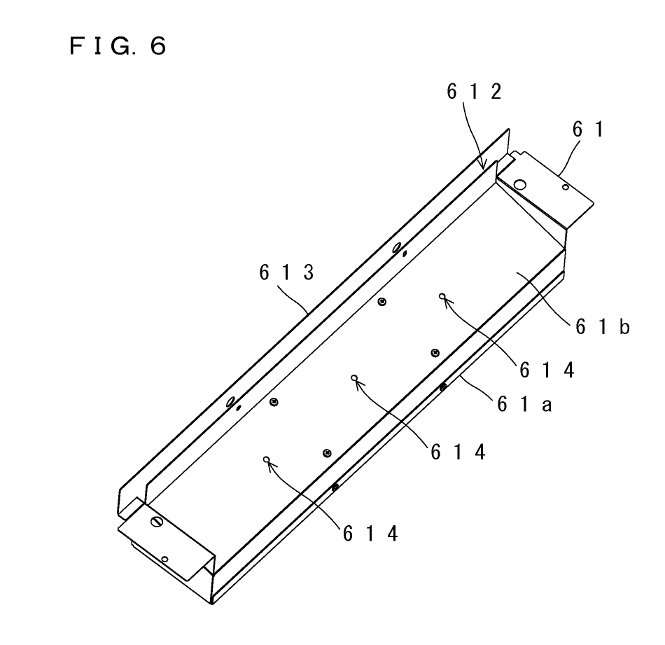

Additionally, as shown in FIG. 6, three through holes 614, 614, and 614 are formed on the front wall 61b of the right channel defining member 61. As described above, the clearance 201 passing the space near the center of the back surface of the liquid crystal display panel 1 is formed between the front wall 61b and the back surface of the liquid crystal display panel 1. As a consequence, as shown in FIG. 7, the second channel portion 52 defined by the right channel defining member 61 communicates with the space at the back surface of the liquid crystal display panel 1 through each of the through holes 614.

Likewise, three through holes 624, 624, and 624 are formed on the front wall 62b of the left channel defining member 62 (see FIG. 8). As described above, the clearance 202 passing the space near the center of the back surface of the liquid crystal display panel 1 is formed between the front wall 62b and the back surface of the liquid crystal display panel 1. As a consequence, as shown in FIG. 8, the second channel portion 53 defined by the left channel defining member 62 communicates with the space at the back surface of the liquid crystal display panel 1 through each of the through holes 624.

In this manner, inside of the casing 2, as shown in FIG. 4, a second channel 54 that passes the hack surface side of the liquid crystal display panel 1 so as to allow the pair of ventilating ports 31 and 41 to communicate with each other is formed in addition to the channel 5 that passes in the front surface side of the liquid crystal display panel 1 so as to allow the pair of ventilating ports 31 and 41 to communicate with each other.

As shown in FIG. 4, a fan 71 is fitted to each of the right ventilating ports 31 formed on the back wall 22 of the casino 2 in an attitude in which a blowing direction of the fan 71 is oriented inward of the casing 2. Consequently, when the fan 71 performs a blowing operation, air staying in each of the right ducts 32 is sucked into the second channel portion 52, and then, the air sucked into the second channel portion 52 flows into the first channel portion 51 from the right end, as indicated by a solid arrow in FIG. 7.

In contrast, a fan 72 is fitted to each of the left ventilating ports 41 formed on the back wall 22 of the casing 2 in an attitude in which a blowing direction of the fan 72 is oriented outward of the casing 2. Consequently, when the fan 72 performs a blowing operation, air staying in the second channel portion 53 is discharged to each of the left ducts 42, and accordingly, the air staving in the first channel portion 51 flows into the second channel portion 53 from the left end of the first channel portion 51, as indicated by a solid arrow in FIG. 8.

In this manner, as indicated by sold, arrows in FIG. 4, the air flows from right to left in the first channel portion 51, so that the air flows from the right ventilating ports 31 to the left ventilating ports 41 in the channel 5. When the air flows in the channel 5 in the above-described manner, the air outside of the casing 2 is sucked into the second channel portion 52 through each of the right ventilators 3 whereas the air inside of the second channel portion 53 is discharged to the outside of the casing 2 through each of the left ventilators 4.

As the air flows in the channel 5 by the blowing operation by the two fans 71 and 72, part of the air sucked through each of the right ventilators 3 passes the back surface side of the liquid crystal display panel 1, to be discharged outside of the casing 2 from each of the left ventilators 4 Hereinafter, the “right” is referred to as the “suction side” whereas the “left” is referred to as the “discharge side”.

As shown in FIG. 7, a pair of filters 33 and 34 are housed inside of the duct 32 constituting the ventilator 3. Specifically, one filter 33 out of the pair of filters 33 and 34 is housed inside of an opening end 320 formed at the duct. 32 whereas the other filter 34 is disposed at an area in the vicinity of the ventilating port 31, wherein a space is defined between the filters 33 and 34. In other words, one filter 33 is separated from the other filter 34 at an area outside of the installation area of the other filter 34.

As shown in FIG. 8, a pair of filters 43 and 44 are housed inside of the duct 42 constituting the ventilator 4. Specifically, one filter 43 out of the pair of filters 43 and 44 is housed inside of an opening end 420 formed at the duct 42 whereas the other filter 44 is disposed at an area in the vicinity of the ventilating port 41, wherein a space is defined between the filters 43 and 44. In other words, one filter 43 is separated from the other filter 44 at an area outside of the installation area of the other filter 44.

In the above-described image display apparatus, the channel 5 which passes the front surface side of the liquid crystal display panel 1 so as to allow the pair of ventilating ports 31 and 41 to communicate with each other is formed inside of the casing 2. Moreover, when the two fans 71 and 72 perform the blowing operation, the air flows from the ventilating port 31 on the suction side toward the ventilating port 41 on the discharge side in the channel 5. Accordingly, the air outside of the casing 2 is sucked into the channel 5 through each of the ventilators 3 on the suction side, and then, the air staying inside of the channel 5 is discharged to the outside of the casing 2 through each of the ventilator 4 on the discharge side.

Consequently, the air outside of the casing 2 sucked into the channel 5 passes between the screen 10 of the liquid crystal display panel 1 and the image display window 20 of the casing 2. At this time, heat is absorbed from the screen 10 of the liquid crystal display panel 1. The air heated by the absorbed heat is discharged to the outside of the casing 2 through each of the ventilators 4 on the discharge side. In this manner, the screen 10 of the liquid crystal display panel 1 is cooled by the air outside of the casing 2. Hence, even in the case where sunlight is incident on the image display window 20 to thus heat the screen 10 of the liquid crystal display panel 1, the temperature increase of the screen 10 of the liquid crystal display panel 1 can be suppressed, and consequently, the liquid crystal display panel 1 is kept to be normally operated.

In the above-described image display apparatus, the second channel 54 which passes the back surface side of the liquid crystal display panel 1 so as to allow the pair of ventilating ports 31 and 41 to communicate with each other is further formed inside of the casino 2. Moreover, as the air flows inside of the channel 5 by the blowing operation by the two fans 71 and 72, part of the air sucked through each of the ventilators 3 on the suction side passes the back surface side of the liquid crystal display panel 1 to be thus discharged to the outside of the casing 2 through each of the ventilators 4 on the discharge side.

In this manner, the liquid crystal display panel 1 is cooled also on the back surface side by the air outside of the casing 2. As a consequence, the liquid crystal display panel 1 as a whole can be efficiently cooled. The circuit board 11 attached to the back surface of the liquid crystal display panel 1 is cooled by the air outside of the casing 2, to be thus prevented from being broken due to overheat.

In the above-described image display apparatus, the pair of filters 33 and 34 are housed inside of the duct 32 constituting the ventilator 3 on the suction side. Consequently, dust, iron powder, or the like contained in the air outside of the casing 2 is removed by the pair of filters 33 and 34 when the air passes the ventilator 3. In this manner, the air hardly containing dust, iron powder, or the like can be sucked into the channel 5.

Likewise, the pair of filters 43 and 44 are housed inside of the duct 42 constituting the ventilator 4 on the discharge side. Consequently, dust, iron powder, or the like which intends to intrude into the channel 5 from the ventilator 4 is removed by the pair of filters 43 and 44.

Thus, in the above-described image display apparatus, a failure of the liquid crystal display panel 1 which may be caused by dust, iron powder, or the like can be prevented.

Additionally, in she above-described image display apparatus, the pair of filters 33 and 34 are disposed separately from each other. Therefore, in comparison with the case where the pair of filters 33 and 34 are disposed in contact with each other, their filtering performance is enhanced. The same goes for the pair of filters 43 and 44.

2. Configuration for Notifying Clogging in Filter

The dust, the iron powder, or the like removed by the pair of filters 33 and 34 is accumulated in the filters 33 and 34 housed inside of the ventilator 3 on the suction side. When the accumulation amount of dust, iron powder, or the like is increased, the filters 33 and 34 clog, thereby interfering the suction of the air into the channel 5. As a consequence, the suction amount of air into the channel 5 is reduced, so that the temperature of the liquid crystal display panel 1 is increased. In the case where the filters 33 and 34 clog, the filters need be replaced with new ones. However, when replacement timing is missed, the temperature of the liquid crystal display panel 1 is excessively increased, and therefore, the liquid crystal display panel 1 is liable to be abnormally operated. The same goes for the case where the filters 43 and 44 housed inside of the ventilator 4 on the discharge side clog so that the discharge amount of air from the channel 5 is reduced.

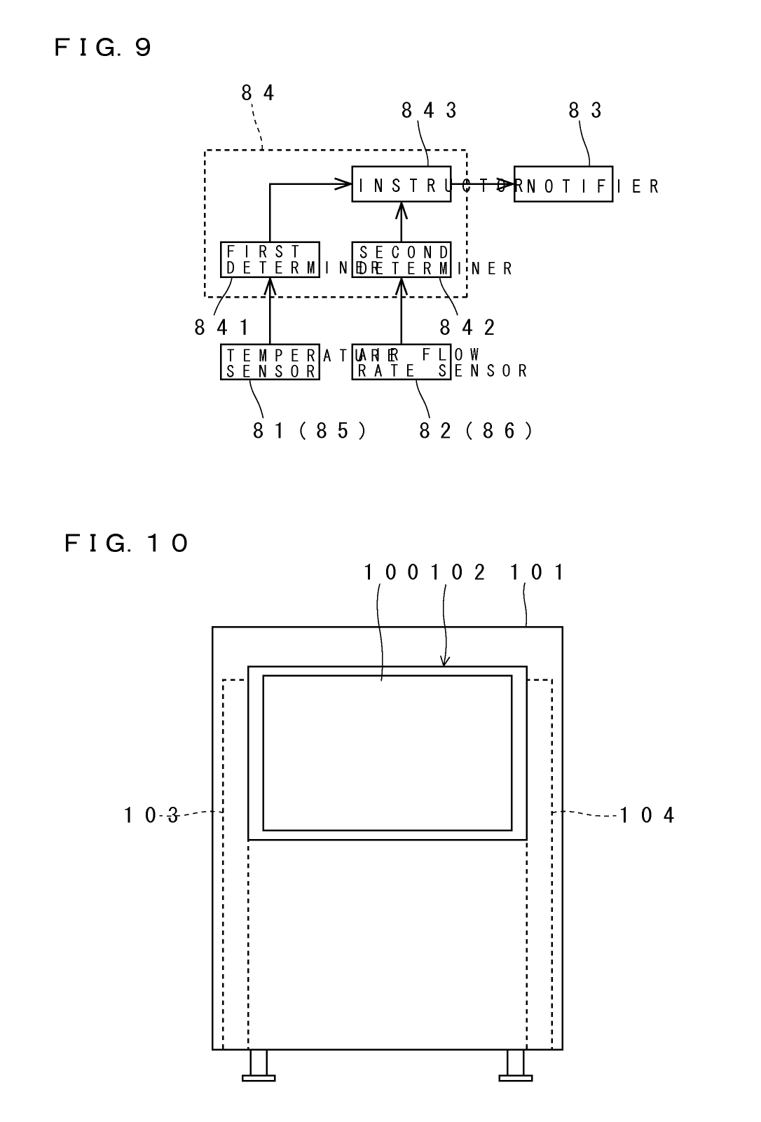

In view of the above, as shown in FIG. 9, the image display apparatus according to the present embodiment further includes: a temperature sensor 81 for acquiring temperature information which is changed according to the temperature of the liquid crystal display panel 1; an air flow rate sensor 82 for acquiring air flow rate information which is changed according to the flow rate of the air flowing in the ventilator 3 on the suction side; a notifier 83 for performing a notifying operation so as to notify occurrence of clogging in the filters 33 and 34; and a controller 84 for controlling the notifying operation performed by the notifier 83 based on the temperature information acquired by the temperature sensor 31 and the air flow rate information acquired by the air flow rate sensor 82.

Here, as shown in FIG. 7, the temperature sensor 81 is housed inside of the channel defining member 61 on the suction side. Moreover, the air flow rate sensor 32 is disposed at an area between the pair of filters 33 and 34 inside of the ventilator 3 on the suction side, and thus, acquires the air flow rate information which is changed according to the flow rate of the air to be discharged through, the filter 33. When the filter 33 clogs, the flow rate of the air to be discharged through the filter 33 becomes greater than that when the filter 33 does not clog.

As shown in FIG. 9, the controller 84 includes: a first determiner 841 for determining whether or not the temperature of the liquid crystal display panel 1 is higher than a predetermined temperature based on the temperature information acquired by the temperature sensor 81; a second determiner 842 for determining whether or not the flow rate of the air flowing in the ventilator 3 is higher than a predetermined flow rate based on the air flow rate information acquired by the air flow rate sensor 82; and an instructor 843 for instructing the notifier 83 to perform the notifying operation based on the determination results by the first determiner 841 and the second determiner 842.

Specifically, the instructor 843 instructs the notifier 83 to perform the notifying operation when either one of the pair of filters 33 and 34 clogs to increase the temperature of the liquid crystal display panel 1 so that the first determiner 841 determines that the temperature of the liquid crystal display panel 1 is higher than the predetermined temperature or when the filter 33 clogs to increase the flow rate of the air flowing in the ventilator 3 on the suction side so that the second determiner 842 determines that the flow rate of the air flowing in the ventilator 3 is higher than the predetermined flow rate.

In the image display apparatus according to the present embodiment, as shown in FIG. 8, a second temperature sensor 85 for acquiring the temperature information which is changed according to the temperature of the liquid crystal display panel 1 is housed inside of the channel defining member 62 on the discharge side, and further, a second air flow rate sensor 86 for acquiring the air flow rate information which is changed according to the flow rate of the air flowing in the ventilator 4 is housed in the ventilator 4 on the discharge side. In this manner, the controller 84 performs the same control as described above based on the temperature information acquired by the second temperature sensor 85 and the air flow rate information acquired by the second air flow rate sensor 86 (see FIG. 9).

In the above-described image display apparatus, the notifier 83 notifies the occurrence of the clogging immediately after any one of the filters 33 and 34 disposed in the ventilator 3 on the suction side and the filters 43 and 44 in the ventilator 4 on the discharge side clogs. Thus, an excessive temperature increase of the liquid crystal display panel 1 can he prevented without missing replacement timing for the filters 33 and 34.

3. Implementation Example of the Image Display Apparatus

As shown in FIG. 10, the above-described image display apparatus can be mounted on a vending machine 101 installed outdoors, and then, be used. In FIG. 10, the image display apparatus is designated by reference numeral 100. The vending machine 101 includes a window 102 used for fixing the image display apparatus 100, and further, a pair of second ducts 103 and 104 extending toward the bottom of the vending machine 101 on both sides of a mounting area for the image display apparatus 100. Each of the lower ends of the pair of second ducts 103 and 104 is opened to the bottom surface of the vending machine 101 whereas the upper ends of the pair of second ducts 103 and 104 are formed into a shape connectable to the right and left ducts 32 and 42 formed in the image display apparatus 100, respectively.

In the above-described embodiment, the air outside of the vending machine 101 is sucked into the channel 5 in the image display apparatus 100 through the pair of ducts 103 and 104 in the vending machine 101, and further, the air staying inside of the channel 5 is discharged to the outside of the vending machine 101. In this manner, the image display apparatus 100 can be kept to be normally operated also in the vending machine 101.

Here, the configuration of each of the constituent elements according to the present invention is not limited to that in the above-described embodiment, and therefore, it can be variously modified within the technical scope of claims. In the above-described image display apparatus, the pair of second channel portions 52 and 53 extend rearward from the first channel portion 51 through both of the right and left sides of the liquid crystal display panel 1. However, the present invention is not limited to this. For example, the pair of second channel portions 52 and 53 may extend rearward from the first channel portion 51 through both of the upper and lower sides of the liquid crystal display panel 1.

Moreover, in the above-described image display apparatus, the pair of ventilating ports 31 and 41 are formed on the back wall 22 of the casing 2 in the positional relationship of the lateral arrangement. However, the present invention is not limited to this. For example, the pair of ventilating ports 31 and 41 may be formed on the back wall 22 of the casing 2 in the positional relationship of the vertical arrangement or on both side walls of the casing 2.

Additionally, in the above-described image display apparatus, only either one of the fans 71 and 72 may be disposed. In addition, in the above-described image display apparatus, the controller 84 may control the notifying operation performed by the notifier 83 based on only the information acquired by either one of the temperature sensor 81 and the air flow rate sensor 82. In the same manner, the controller 84 can control the notifying operation performed by the notifier 83 based on only the information acquired by either one of the second temperature sensor 85 and the second air flow rate sensor 86.

Furthermore, the various configurations adopted in the above-described image display apparatus are not limited to the image display apparatus provided with the liquid crystal display panel 1 but may be applied to image display apparatuses provided with various kinds of image display panels such as a plasma display panel and an organic EL (Electro-Luminescence) display panel.

1. (canceled)

2. (canceled)

3. (canceled)

4. (canceled)

5. An image display apparatus comprising:
an image display panel;
a casing housing the image display panel therein;
a ventilator found in the casing so as to allow the inside of the casing and the outside to communicate with each other;
blowing unit configured to introduce air from the ventilator to the inside of the casing; and
first and second filters housed inside of the ventilator,
the first filter being disposed apart from the second filter at an area outside of an installation area of the filter.

6. The image display apparatus according to claim 5, further comprising:
a temperature sensor that acquires temperature information changed according to temperature of the image display panel and/or an air flow rate sensor that acquires air flow rate information changed according to a flow rate of air flowing inside of the ventilator;
notifying unit configured to perform a notifying operation for notifying occurrence of clogging in the filter;
and control unit configured to control the notifying operation performed by the notifying unit based on the temperature information acquired by the temperature sensor and/or the air flow rate information acquired by the air flow rate sensor.

7. A display apparatus comprising:
a display panel;
a light translucent member disposed in a front surface of the display panel; and
a generator configured to generate an air flow in a space defined by the display panel and the light translucent member,
the generator including a fan for discharging disposed at one side surface of the display panel.

8. The display apparatus according to claim 7, wherein the generator includes a fan for sucking disposed at the other side surface of the display panel.

9. A display apparatus according to claim 7, further comprising a vertically extending duct disposed sideways of the casing, wherein
air passing the fan for discharging is discharged to the outside through the duct.
